(19) United States
(12) Patent Application Publication
(10) Pub. No.: US 2010/0127272 A1
(43) Pub. Date: May 27, 2010

(54) THIN FILM TRANSISTOR ARRAY PANEL AND MANUFACTURING METHOD THEREOF

(75) Inventors: Youn-Hak JEONG, Cheonan-si (KR); Keun-Chan Oh, Cheonan-si (KR); Yeon-Sik Ham, Suwon-si (KR); Dong-Gi Seong, Seongnam-si (KR); Kang-Woo Kim, Seoul (KR); Yeon-Mun Jeon, Iksan-si (KR); Hee-Hwan Lee, Busan (KR)

Correspondence Address: H.C. PARK & ASSOCIATES, PLC, 8500 LEESBURG PIKE, SUITE 7500, VIENNA, VA, 22182, US

(73) Assignee: Samsung Electronics Co., Ltd., Suwon-si (KR)

(21) Appl. No.: 12/428,136

(22) Filed: Apr. 22, 2009

(30) Foreign Application Priority Data
Nov. 26, 2008 (KR) 10-2008-0118224

(51) Int. Cl. H01L 33/00; H01L 21/28

(52) U.S. Cl. 257/72; 438/30; 257/E33.064; 257/E33.055; 257/E21.158; 438/587

(57) ABSTRACT

A thin film transistor array panel according to the present invention includes: a gate line formed on a substrate; a data line insulated from and intersecting the gate line; a thin film transistor connected to the gate line and the data line; a light blocking layer formed on the thin film transistor and having a first transmitting window; a reflection layer formed on the light blocking layer and a second transmitting window overlapping the first transmitting window; a color filter formed in the first transmitting window and the second transmitting window and on the reflection layer; and a pixel electrode formed on the color filter and overlapping the second transmitting window, wherein the reflection layer includes protrusions and depressions corresponding to a portion of the pixel area defined by the gate line and data line.

### CROSS-REFERENCE TO RELATED APPLICATION

This application claims priority from and the benefit of Korean Patent Application No. 10-2008-0118224, filed on Nov. 26, 2008, which is hereby incorporated by reference for all purposes as if fully set forth herein.

### BACKGROUND OF THE INVENTION

1. Field of the Invention

The present invention relates to a thin film transistor array panel and a manufacturing method thereof.

2. Discussion of the Background

A liquid crystal display is a type of flat panel display that is widely used at present. A liquid crystal display includes two display panels in which field generating electrodes such as pixel electrodes and a common electrode are formed, and a liquid crystal layer that is interposed therebetween. The liquid crystal display generates an electric field in the liquid crystal layer by applying a voltage to the field generating electrodes, thereby determining a direction of liquid crystal molecules of the liquid crystal layer and displaying an image by controlling the transmittance of light.

However, because the liquid crystal display is a non-emissive device, a light source is required. An LCD may be classified as a transmissive type or a reflective type depending on the type of light source.

In a transmissive type LCD, light emitted from the backlight as a light source that is attached to the rear surface of the liquid crystal panel is incident to the liquid crystal layer such that light transmittance is controlled according to an arrangement of liquid crystal molecules to display images. In the liquid crystal display of the reflective type, natural external light or artificial light is reflected and the light transmittance is controlled according to arrangement of the liquid crystal molecules.

The transmissive type of liquid crystal display generates bright images that can be displayed in a dark environment since it uses a rear light source, but high power consumption is generated, while the reflective type liquid crystal display consumes little power in comparison with the transmissive type of liquid crystal display since it depends on external natural light or external artificial light, but it is difficult to use in a dark environment.

Accordingly, a transflective type of liquid crystal display that can appropriately select from a reflection mode and a transmissive mode according to the circumstance has been suggested.

In the transflective LCD, a reflection region and a transmission region are provided in a single pixel area.

However, a path of light passing through a color filter differs depending on whether the light is traveling through a transmission region or a reflection region such that color reproducibility varies due to differences in light paths.

### SUMMARY OF THE INVENTION

The present invention improves color reproducibility based on light path, and simplifies the manufacturing method.

The present invention also provides a thin film transistor array panel.

Additional features of the invention will be set forth in the description which follows, and in part will be apparent from the description, or may be learned by practice of the invention.

The present invention discloses a thin film transistor array panel comprising a gate line formed on a substrate; a data line insulated from and intersecting the gate line; a thin film transistor connected to the gate line and the data line; a light blocking layer formed on the thin film transistor and having a first transmitting window; a reflection layer formed on the light blocking layer and a second transmitting window overlapping the first transmitting window; a color filter formed in the first transmitting window and the second transmitting window and on the reflection layer; and a pixel electrode formed on the color filter and overlapping the second transmitting window, wherein the reflection layer includes protrusions and depressions corresponding to a portion of the pixel area defined by the gate line and data line.

The present invention also discloses a manufacturing method for a thin film transistor array panel comprising: forming a gate line on a substrate; forming a data line insulated from and intersecting the gate line; forming a thin film transistor connected to the gate line and the data line; forming a light blocking layer having a first transmitting window corresponding to a portion of the pixel area defined by the gate line and the data line; forming a reflection layer having a second transmitting window corresponding to the first transmitting window on the light blocking layer; forming a color filter on the reflection layer including the first and second transmitting windows; and forming a pixel electrode connected to the thin film transistor on the color filter, wherein the forming of the light blocking layer includes forming protrusions and depressions on the surface of the portion corresponding to the pixel area by using slits or a transflective layer.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a layout view of a thin film transistor array panel according to an exemplary embodiment of the present invention.

FIG. 2 is a cross-sectional view taken along line II-II of FIG. 1

FIG. 3, FIG. 4, FIG. 5 and FIG. 6 are cross-sectional views sequentially showing a thin film transistor array panel in the manufacturing method of the thin film transistor array panel according to an exemplary embodiment of the present invention.

FIG. 7 is a layout view of a thin film transistor array panel according to another exemplary embodiment of the present invention.

FIG. 8 is a cross-sectional view of the thin film transistor array panel shown in FIG. 7 taken along the line VIII-VIII.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element such as a layer, film, region or substrate is referred to as being “on” another element, it can be directly on the other element or intervening elements may also be present. In contrast, when an element is referred to as being “directly on” another element, there are no intervening elements present.

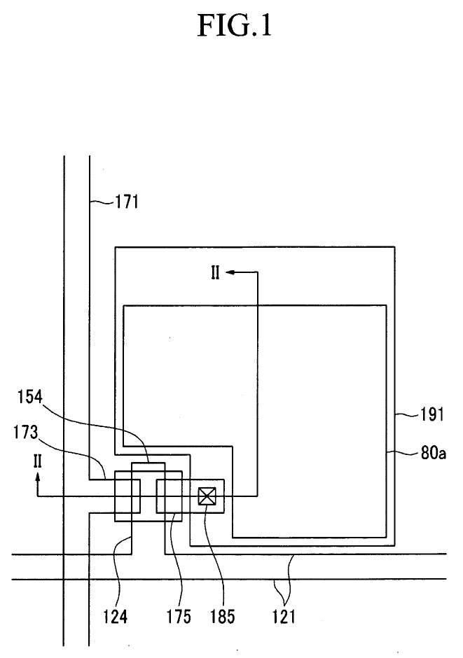

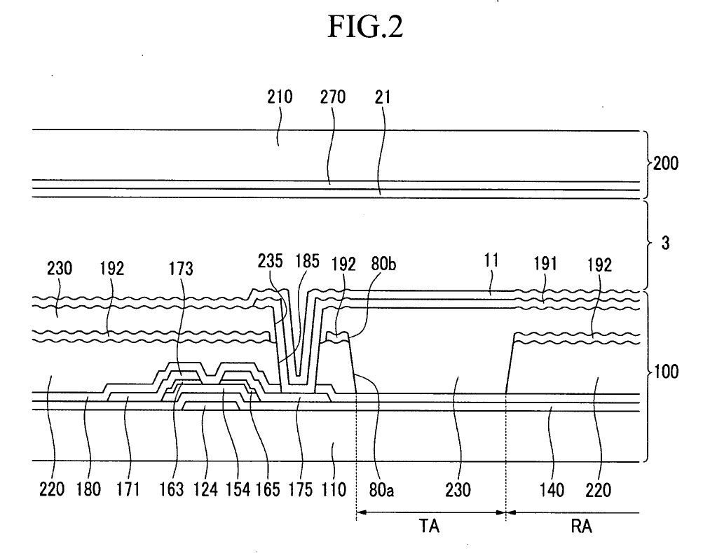

Now, a thin film transistor array panel according to an exemplary embodiment of the present invention will be described with reference to FIG. 1 and FIG. 2.

FIG. 1 is a layout view of a thin film transistor array panel according to an exemplary embodiment of the present invention, and FIG. 2 is a cross-sectional view of the thin film transistor array panel shown in FIG. 1 taken along the line II-II

Referring to FIG. 1 and FIG. 2, a liquid crystal display according to the present exemplary embodiment includes a thin film transistor array panel 100 and a common electrode panel 200 that face each other, and a liquid crystal layer 3 interposed therebetween.

The thin film transistor array panel 100 will now be described.

A plurality of gate lines 121 are formed on an insulating substrate 110 which may be made of transparent glass, plastic, etc.

The gate lines 121 transmit gate signals and extend in a transverse direction. Each of the gate lines 121 includes a plurality of gate electrodes 124 protruding upward, and an end portion (not shown) having a wide area for connecting to other layers or an external driving circuit (not shown).

A gate insulating layer 140 is formed on the gate line 121. The gate insulating layer 140 may be made of silicon nitride (SiNx) or silicon oxide (SiOx), etc.

A plurality of semiconductor islands 154 which may be made of amorphous silicon are formed on the gate insulating layer 140. The semiconductor islands 154 overlap the gate electrodes 124.

A plurality of pairs of ohmic contact islands 163 and 165 are formed on the semiconductor islands 154. The ohmic contacts 163 and 165 may be made of silicide or n+ hydrogenated amorphous silicon in which an n-type impurity such as phosphorus is highly doped.

A plurality of data lines 171 and a plurality of drain electrodes 175 are formed on the ohmic contacts 163 and 165 and the gate insulating layer 140.

The data lines 171 transfer data voltages, and mainly extend in a longitudinal direction thereby crossing the gate lines 121. Each of the data lines 171 includes a plurality of source electrodes 173 extending toward the gate electrodes 124.

The drain electrodes 175 are separated from the data lines 171, and are opposite to the source electrodes 173 with respect to the gate electrodes 124. A wide-end portion (not shown) of the data lines 171 may be connected with another layer (not shown).

A passivation layer 180 is formed on the data lines 171 and the drain electrodes 175. The passivation layer 180 may be made of an inorganic material such as silicon nitride or silicon oxide, and it prevents the channel of the semiconductor 154 from being contaminated. However, the passivation layer 180 may be omitted if necessary.

A light blocking layer 220 having a first transmitting window 80a is formed on the passivation layer 180. The light blocking layer 220 may be made of an organic material including a black color pigment.

The pixel area defined by the gate line 121 and the data line 171 is divided into a transmission region TA corresponding to the transmitting window 80a and a reflection region RA excluding for the transmitting window 80a, and protrusions and depressions are formed in the surface of the light blocking layer 220 disposed in the reflection region RA.

A reflection layer 192 which includes a second transmitting window 80b overlapping the first transmitting window 80a is formed on the light blocking layer 220. The reflection layer 192 may be made of a reflective metal such as aluminum, silver, chromium, or alloys thereof. The reflection layer 192 includes protrusions and depressions. The protrusions and depressions induce diffused reflection of the light, thereby preventing an object from being reflected on the screen.

The reflection layer 192 is formed on the whole surface of the substrate 110 like the light blocking layer 220, thereby overlapping the thin film transistor such that light leakage generated by light incident to the semiconductor island 154 may be prevented. The reflection layer 192 may have the same plane shape as the light blocking layer 220, but may only be formed in the pixel area. The light blocking layer 220 may be made of the organic material including a black color pigment such as carbon.

A plurality of color filters 230 are formed on the reflection layer 192 including on the second transmitting window 80b. The color filters 230 may be extended in the longitudinal direction according to a pixel column, thereby forming a stripe. Each color filter 230 may display one of primary colors such as three primary colors of red, green, and blue. The color filters 230 are filled in the first and second transmitting windows 80a and 80b, and the portion of the color filter 230 formed on the light blocking layer 220 may be thinner than the portion of the color filter 230 formed in the transmitting windows 80a and 80b. Here, the portion of the color filter 230 formed in the transmitting windows 80a and 80b is thicker than portion of the color filter 230 formed on the light blocking layer 220 by about 1.2-3 times.

In the transmission region TA, light incident from outside of substrate 110 passes through the liquid crystal layer 3 and is output in the opposite direction to the incident direction, thereby displaying an image. However, in the reflection region RA, the light incident from the outside of the substrate 110 is input to the liquid crystal layer 3 and reflected by the reflection layer 192 to again pass through the liquid crystal layer 3. Thus in the reflection region RA light is turned back in the incident direction to thereby display images.

In an exemplary embodiment of the present invention, the thicknesses of the color filters 230 of the reflection region RA and the transmission region TA are different from each other such that the length of the path passing through the color filters 230 may be the same in the reflection region RA and the transmission region TA, thereby minimizing the difference in color reproducibility between the two regions.

When the upper portion of the color filters 230 is planarized, the thickness (cell gap) of the liquid crystal layer 3 is the same in the reflection region RA and the transmission region TA, however the thickness of the color filter 230 and the light blocking layer 220 may be controlled and thereby the cell gap of the reflection region RA is narrower than the cell gap of the transmission region TA. Accordingly, the length of the path passing through the liquid crystal layer 3 may be the same in the reflection region RA and the transmission region TA such that the reflection region RA and the transmission region TA may have the same gamma curves.

A pixel electrode 191 which may be made of a transparent conductive material such as indium tin oxide (ITO) or indium zinc oxide (IZO) is formed on the color filter 230.

The pixel electrode 191 is formed on the reflection region RA and the transmission region RA, and is connected to the drain electrode 175 through a through hole 235 of the color filter 230, and a contact hole 185 is formed in the light blocking layer 220 and the passivation layer 180.

Next, the common electrode panel 220 will be described.

A common electrode 270 is formed on an insulation substrate 210 which may be made of transparent glass or plastic. The common electrode 270 may be made of a transparent conductor such as ITO or IZO.

Alignment layers 11 and 21 are respectively formed on the inner surfaces of the display panels 100 and 200. Polarizers (not shown) may be provided on the outer surfaces of the display panel 100 and 200.

When the surface of the color filter 230 is substantially planarized in an exemplary embodiment of the present invention, a step is not formed in the liquid crystal layer 3. Accordingly, the arrangement of the liquid crystal is not tilted by steps, and thereby the arrangement of the liquid crystal may be stably obtained.

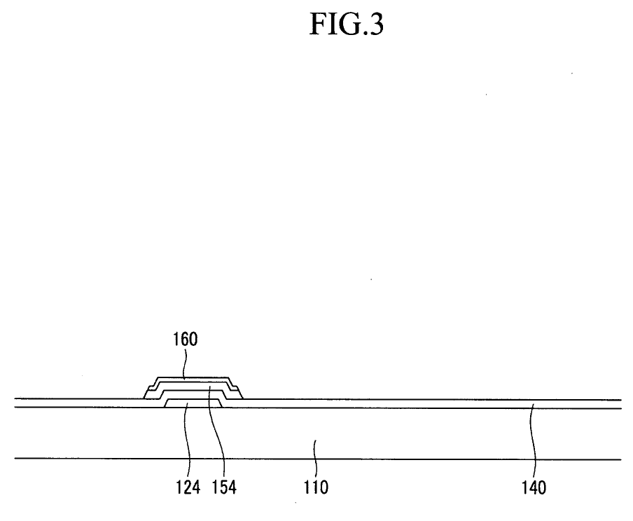

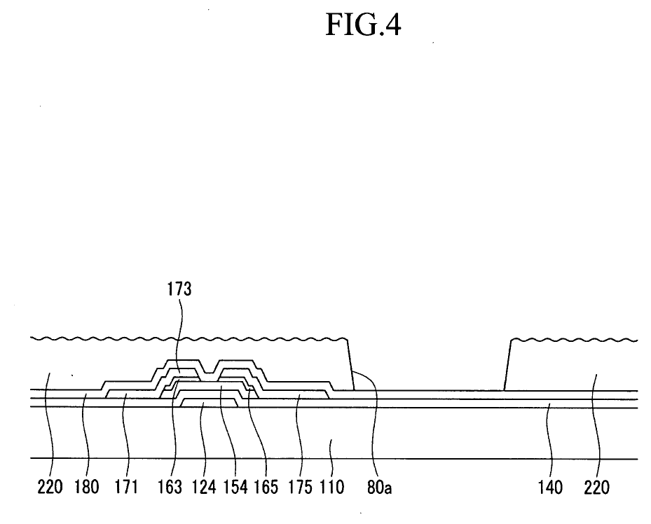

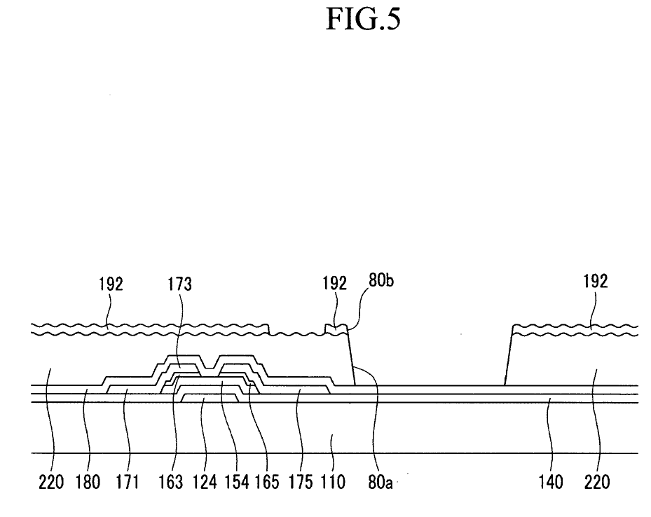

Next, a manufacturing method of the thin film transistor array panel or the liquid crystal display will be described with reference to FIG. 3, FIG. 4, FIG. 5 and FIG. 6.

FIG. 3, FIG. 4, FIG. 5 and FIG. 6 are cross-sectional views sequentially showing a thin film transistor array panel in the manufacturing method of the thin film transistor array panel according to an exemplary embodiment of the present invention.

As shown in FIG. 3, a gate line including a gate electrode 124 is formed on a substrate 110.

Next, a gate insulating layer 140 is formed on the gate line, and an amorphous silicon layer which does not include an impurity and an amorphous silicon layer which includes an impurity are deposited on the gate insulating layer 140 and patterned to form a semiconductor island 154 and an ohmic contact pattern 160.

As shown in FIG. 4, a metal layer is deposited on the ohmic contact pattern 160 and patterned to form a data line 171 which includes a source electrode 173 that protrudes from data line 171 and a drain electrode 175. Then, the ohmic contact pattern 160 is etched by using the data line 171 and the drain electrode 175 as a mask to form ohmic contact islands 163 and 165.

An inorganic material is deposited on the data line 171 and the drain electrode 175 to form a passivation layer 180.

An organic material including black color pigments is coated on the passivation layer 180 and patterned to form a light blocking layer 220 having a first transmitting window 80a. Here, protrusions and depressions may be formed on the surface of the light blocking layer 220 through exposure and development using slits or a transflective layer.

As shown in FIG. 5, a reflection metal is deposited on the light blocking layer 220 and patterned to form a reflection layer 192 having a second transmitting window 80b. Here, a portion of the reflective layer 192 overlapping the drain electrode 175 is partially removed. The reflection layer 192 is formed according to the protrusions and depressions of the light blocking layer 220, thereby having a surface with protrusions and depressions.

As shown in FIG. 6, a color filter 230 is formed on the reflection layer 192. Here, a portion of the color filter 230 is patterned to have a through hole 235 overlapping the drain electrode 175.

Next, the light blocking layer 220 and the passivation layer 180 exposed through the through hole 235 are etched to form a contact hole 185 exposing the drain electrode 175. The contact hole of the light blocking layer 220 may be formed along with the transmitting window 80a when forming the light blocking layer 220.

As shown in FIG. 2, a transparent material is deposited on the color filter 230 and patterned to form a pixel electrode 191 which is connected to the drain electrode 175 through the contact hole 185.

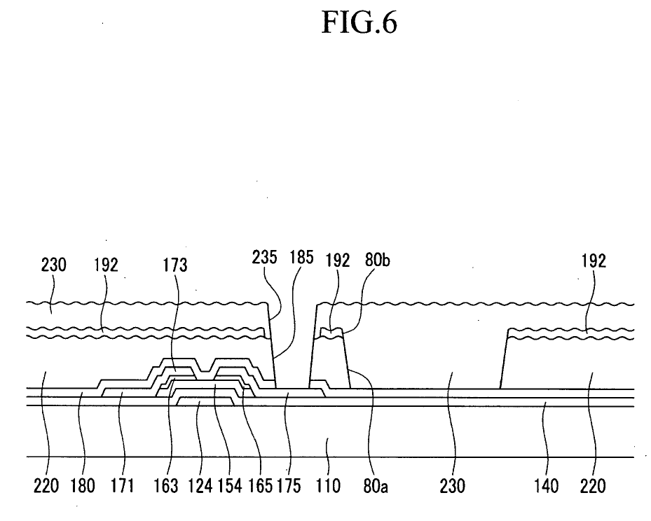

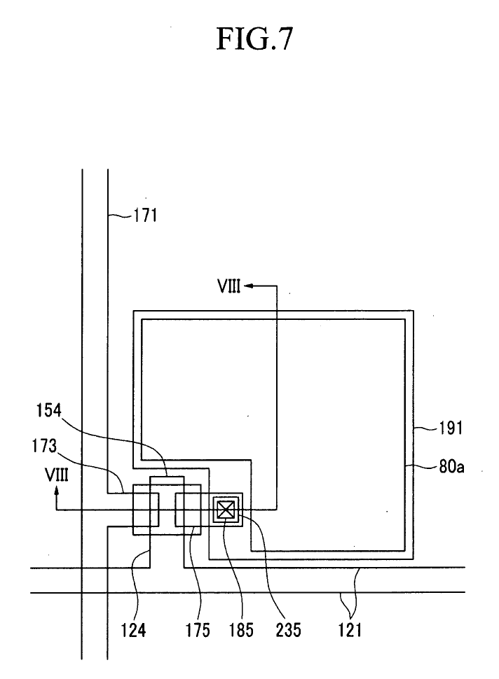

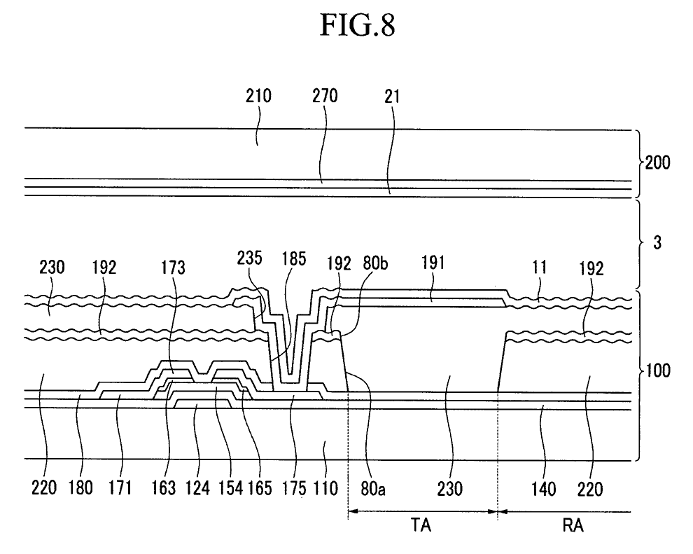

FIG. 7 is a layout view of a thin film transistor array panel according to another exemplary embodiment of the present invention, and FIG. 8 is a cross-sectional view taken along the line VIII-VIII of FIG. 7.

The layered structure of the thin film transistor array panel of FIGS. 7 and 8 is almost the same layered structure as the thin film transistor panel shown in FIG. 1 and FIG. 2, so only portions that are different from the thin film transistor panel shown in FIG. 1 and FIG. 2 will be described.

Referring to FIG. 7 and FIG. 8, a through hole 235 of the color filter 230 is wider than the contact hole 185. Accordingly, a portion of the reflection layer 192 is exposed through the through hole 235, and the pixel electrode 191 is electrically connected to the exposed reflection layer 192.

Also, the pixel electrode 191 is only formed in the transmission region TA. Here, the color filter 230 may be exposed, however the alignment layer 11 is formed thereon such that the liquid crystal layer 3 is not contaminated.

Accordingly, if the pixel electrode 191 and the reflection layer 192 are electrically connected to each other, a distance difference is generated by the thickness of the color filter 230 such that a voltage difference between the pixel electrode 191 and the common electrode 270 is different from the voltage difference between the reflection layer 192 and the common electrode 270, and thereby the two regions may be driven dually. Accordingly, if the thickness of the color filter 230 is controlled, even though the cell gaps of the liquid crystal are the same in the transmission region TA and the reflection region RA, a curved line (V-T curve) of the transmittance according to the voltage may be the same in the transmission region TA and the reflection region RA.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A thin film transistor array panel comprising:
a gate line arranged on a substrate;
a data line insulated from and crossing the gate line;
a thin film transistor connected to the gate line and the data line;
a light blocking layer arranged on the thin film transistor and comprising a first transmitting window;
a reflection layer arranged on the light blocking layer and comprising a second transmitting window overlapping the first transmitting window;
a color filter arranged in the first transmitting window and the second transmitting window and on the reflection layer; and
a pixel electrode arranged on the color filter and overlapping the second transmitting window,
wherein the reflection layer comprises protrusions and depressions corresponding to a portion of a pixel area defined by the gate line and data line.

2. The thin film transistor array panel of claim 1, wherein
the light blocking layer is arranged on the entire surface of the substrate.

3. The thin film transistor array panel of claim 2, wherein
the reflection layer is formed on the entire surface of the substrate.

4. The thin film transistor array panel of claim 3, wherein
the light blocking layer and the reflection layer have the same planar pattern.

5. The thin film transistor array panel of claim 1, wherein
an upper surface of the color filter overlapping the reflection layer comprises protrusions and depressions.

6. The thin film transistor array panel of claim 1, wherein
the color filter includes a first portion overlapping the transmitting window and a second portion overlapping the reflection layer, and the thickness of the first portion is 1.2-3 times the thickness of the second portion.

7. The thin film transistor array panel of claim 1, wherein
the pixel electrode is electrically connected to the reflection.

8. The thin film transistor array panel of claim 7, wherein
the pixel area includes a first portion overlapping the transmitting window and a second portion overlapping the reflection, and
the pixel electrode is formed on the first portion and does not exist on the second portion.

9. The thin film transistor array panel of claim 1, further comprising
a passivation layer formed between the thin film transistor and the light blocking layer.

10. The thin film transistor array panel of claim 9, wherein
the passivation layer is made of an inorganic material.

11. The thin film transistor array panel of claim 1, wherein
the pixel electrode includes a portion overlapping the reflection layer.

12. The thin film transistor array panel of claim 11, wherein
the pixel electrode covers the color filter, thereby preventing it from being exposed.

13. A method for manufacturing a thin film transistor array panel, comprising:
forming a gate line on a substrate;
forming a data line insulated from and intersecting the gate line;
forming a thin film transistor connected to the gate line and the data line;
forming a light blocking layer having a first transmitting window corresponding to a portion of the pixel area defined by the gate line and the data line;
forming a reflection layer having a second transmitting window corresponding to the first transmitting window on the light blocking layer;
forming a color filter on the reflection layer including the first and second transmitting windows; and
forming a pixel electrode connected to the thin film transistor on the color filter,
wherein the forming of the light blocking layer comprises
forming protrusions and depressions on the surface of the portion corresponding to the pixel area by using slits or a transflective layer.

14. The method of claim 13, wherein
the surface of the color filter overlapping the reflection layer comprises protrusions and depressions.

15. The method of claim 13, wherein
a thickness of a portion of the color filter formed in the first transmitting window and the second transmitting windows is 1.2-3 times a thickness of a portion of the color filter formed on the light blocking layer.

16. The method of claim 13, wherein
the pixel electrode comprises a transparent conductive material.

17. The thin film transistor array panel of claim 1, wherein an upper surface of the color filter overlapping the reflection layer comprises protrusions and depressions, and an upper surface of the color filter in the first transmitting window and the second transmitting window is planar.
